(19) United States
(12) Patent Application Publication
(10) Pub. No.: US 2012/0020032 A1
(43) Pub. Date: Jan. 26, 2012

(54) ELECTRIC BUTTON AND LED BUTTON MODULE

(75) Inventors: Hong Hsu HUANG, Taipei City (TW); Chih Chang Fang, Taipei City (TW); James Lee, Taipei City (TW)

(73) Assignee: KING'S METAL FIBER TECHNOLOGIES CO., LTD., Taipei City (TW)

(21) Appl. No.: 12/965,287

(22) Filed: Dec. 10, 2010

(30) Foreign Application Priority Data
Jul. 20, 2010 (TW) 099123852

(51) Int. Cl. H05K 7/00

(52) U.S. Cl. 361/748

(57) ABSTRACT

An electric button is provided. The electric button comprises a substrate with a plurality of through holes thereon, at least an electric component fixedly disposed on the surface of the substrate and electrically connecting to the substrate, and a mask sealing the electric component on the surface of the substrate. The substrate is sewed onto the fabric by at least a conductive thread through the through holes and electrically connected to the conductive thread. Thereby, if a power supply is connected through the conductive thread to the substrate, the electrical power would be further connected to the electric component so that the electric component can perform its function.

This application claims the benefit of priority based on Taiwan Patent Application No. 099123852 filed on Jul. 20, 2010, which is hereby incorporated by reference in its entirety.

### CROSS-REFERENCES TO RELATED APPLICATIONS

Not applicable.

### BACKGROUND OF THE INVENTION

1. Field of the Invention

The present invention provides an electric button and a light emitting diode (LED) module. In particular, the present invention provides an electric button that can be loaded with an electric component and an LED button module in a button form.

2. Descriptions of the Related Art

Buttons have been used for many years for buttoning and ornamental purposes on clothing and fabrics in human society. Although their functions are only limited thereto, buttons are one of the most essential and indispensable clothing accessories in clothing.

Recently, with the great progress of science and technology, a wide variety of electric components that are both small and have independent functions have been developed. However, most of these electric components are designed to be used in various electric devices. Few of these electronic components are applied to clothing and fabrics and even fewer are used in combination with clothing accessories. Accordingly, if functions of these electric components can be integrated with clothing accessories, then the functions of the various electric components can be applied to more clothing and fabrics to add convenience for the user.

### SUMMARY OF THE INVENTION

An objective of the present invention is to integrate an electric component into a clothing accessory (e.g., a button) so that a conventional button can not only perform the traditional buttoning and ornament functions but also have an electric component, thereby adding new functions to clothing and fabrics for the users' convenience.

To achieve the aforesaid objective, an embodiment of the present invention provides an electric button, which comprises a substrate, at least one electric component and a mask. The electric component is electrically connected to and fixedly disposed on a surface of the substrate. The mask seals the electric component on the surface of the substrate. The substrate is sewed onto the fabric by at least one conductive thread, and is electrically connected to the conductive thread. The electric component comprises a light emitting diode (LED), a resistor, a capacitor, a switch, an inductor, a speaker, an integrated circuit (IC) chip, the like, or a combination thereof.

Another embodiment of the present invention further provides an electric button, which comprises a substrate, at least one electric component, at least one conductive thread and a mask. The conductive thread fixedly disposes the electric component on the surface of the substrate, and is electrically connected to the electric component. The mask seals the electric component on the surface of the substrate. The substrate is sewed on the fabric by the conductive thread. The electric component comprises an LED, a resistor, a capacitor, a switch, an inductor, a speaker, an IC chip, the like, or a combination thereof.

The aforesaid two kinds of electric buttons, in different ways, can have the electric component integrated into a conventional button or can directly replace the functions of the conventional button so that the functions of the electric component can be additionally provided in the conventional common button to create new application fields and functions.

Yet a further embodiment of the present invention provides an LED button module, which comprises a substrate, a first electrical pin, a second electrical pin, an LED die and a mask. The substrate has a plurality of through holes formed therein. The first electrical pin, the second electrical pin and the LED die are all fixedly disposed on a surface of the substrate. The LED die is electrically connected to the first electrical pin and the second electrical pin respectively. The mask seals the LED die on the surface of the substrate. The substrate is sewed onto the fabric by a conductive thread through the through holes, and the conductive thread is electrically connected to the first electrical pin and the second electrical pin.

Yet another embodiment of the present invention provides an LED button module, which comprises a first electrical pin, a second electrical pin, an LED die and an enclosure. The first electrical pin and the second electrical pin are electrically connected to the LED die, and the enclosure of the LED button module comprises at least one through hole formed therein so that the enclosure is sewed onto the fabric by at least one conductive thread through the through hole. The enclosure can be formed with a base and a housing portion, which are integrally formed, simultaneously through injection molding from a plastic. The base supports the LED die, the first electrical pin and the second electrical pin, while the housing portion seals the first electrical pin, the second electrical pin and the LED die.

Accordingly, the LED button module of the present invention can be sewed onto the fabric just like a conventional button. Thus, apart from the conventional buttoning or ornament function, the LED button module can also serve various LED to create new applications of the fabric.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a top view illustrating the first embodiment of an electric button of the present invention;

FIG. 2 is a side view illustrating the first embodiment of the electric button of the present invention;

FIG. 3 is a top view illustrating the second embodiment of the electric button of the present invention;

FIG. 4 is a side view illustrating the second embodiment of the electric button of the present invention;

FIG. 5 is a top view illustrating the first embodiment of an LED button module of the present invention;

FIG. 6 is a side view illustrating the first embodiment of the LED button module of the present invention;

FIG. 7 is a top view illustrating a second embodiment of the LED button module of the present invention; and

FIG. 8 is a side view illustrating the second embodiment of the LED button module of the present invention.

### DESCRIPTION OF THE PREFERRED EMBODIMENT

In the following descriptions, technical features and efficacies of the present invention will be explained with reference to embodiments thereof. However, these embodiments are not intended to limit the present invention to any specific environment, applications or particular implementations described in these embodiments. Therefore, descriptions of these embodiments are only for the purpose of illustration rather than limitation.

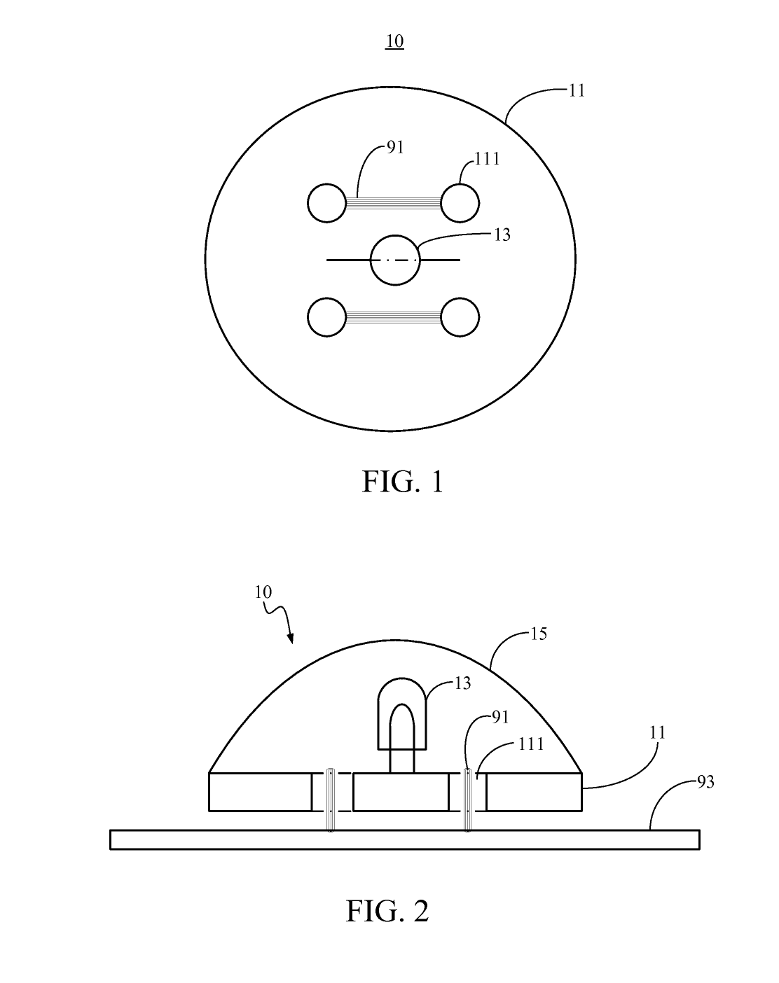

First, in reference to FIGS. 1 and 2, a schematic top view and a schematic side view illustrating the first embodiment of an electric button of the present invention are shown therein. As shown in FIGS. 1 and 2, the electric button 10 of the present invention comprises a substrate 11, at least one electric component 13 and a mask 15. In this embodiment, the substrate 11 has a plurality of through holes 111 formed therein; for example, the substrate 11 has four through holes 111 distributed therein. The through holes 111 function like the through holes of a conventional button, through which the button is fastened onto the fabric by a thread. However, as well-known by people skilled in the art, the number and the form of the aforesaid through holes 111 are only intended to illustrate the present invention but not to limit the present invention. Other conventional ways in which the button is sewed onto the fabric may also be applied to the present invention. For example, in other examples of the present invention, at least one lateral opening may be disposed in the lower part of the substrate to sew the substrate onto the fabric; a set of male and female buttons may also be disposed on the lower part of the substrate to fasten the substrate on the fabric.

Still, in references to FIGS. 1 and 2, the substrate 11 of this embodiment can be sewed onto the fabric 93 by a conductive thread 91 through the through holes 111, and the substrate 11 and the conductive thread 91 are electrically connected to each other. In this embodiment, the substrate 11 should be a printed circuit board (PCB) to support and electrically connect to the electric component 13. Furthermore, it shall be particularly noted that the conductive thread 91 of this embodiment adopts a technology described by the present applicant in U.S. patent application Ser. No. 12/569,882 (corresponding to Taiwan Patent Application No. 099102066) filed on Sep. 29, 2009. This U.S. patent application is incorporated herein by reference, so this technology will not be further described herein.

Secondly, the electric component 13 of this embodiment is electrically connected to a printed circuit and fixedly disposed onto the surface of the substrate 11 preferably by a surface mount technology (SMT) and a welding process. Specifically, the electric component 13 may comprise at least a light emitting diode (LED), a resistor, a capacitor, a switch, an inductor, a speaker and an integrated circuit (IC) chip or a combination thereof; However, the components are not merely limited thereto, and other electric components that can be integrated into the button are all subject matters of the applications of the present invention.

To ensure that the electric component is not influenced by the ambient temperature and humidity and in consideration of different appearance designs of conventional buttons, the electric button 10 of the present invention has a mask 15 adapted to seal the electric component 13 on the surface of the substrate 11. Furthermore, the mask 15 is adapted to seal most of the area of the electric component 13 and the substrate 11 except the through holes so that the electric component 13 and/or the substrate 11 are not influenced by adverse factors of the ambient environment; as a result, both a satisfactory electrical insulation from the ambient environment and an aesthetic appearance can be achieved. In specific embodiments, the mask 15 may have a planar shape or a spherical shape; and depending on the actual requirements, at least one transparent or translucent area may be disposed on the mask to facilitate full functioning of the electric component. In practicality, an external power supply (not shown) is applied to the substrate 11 through the conductive thread 91, and is then electrically connected to the electric component 13 through a printed circuit of the substrate 11 to operate the electric component 13.

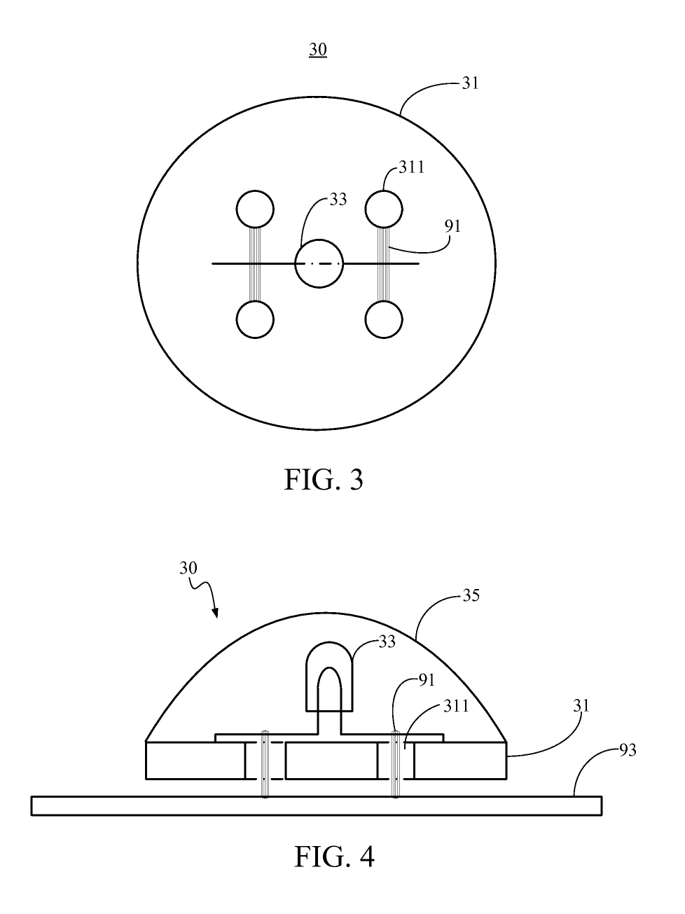

FIGS. 3 and 4 illustrate a top view and a side view illustrating the second embodiment of an electric button 30 of the present invention. As shown in FIGS. 3 and 4, the electric button 30 of the present invention comprises a substrate 31, at least one electric component 33, at least one conductive thread 91 and a mask 35. The second embodiment of the electric button of the present invention is similar to the first embodiment of the electric button 10 except that the electrical connection relationship between the individual components is different. In this embodiment, the substrate 31 is a carrier like a conventional button, and is merely used to support the electric component 33 thereon but is not electrically connected to the electric component 33. The electric component 33 is electrically connected to the conductive thread 91 directly, and is fixedly disposed on the substrate 31 by the conductive thread 91. The conductive thread 91 further extends through the through holes 311 to sew the substrate 31 onto the fabric 93. In practicality, an external power supply (not shown) is applied to the electric component 33 through the conductive thread 91 directly to operate the electric component 33.

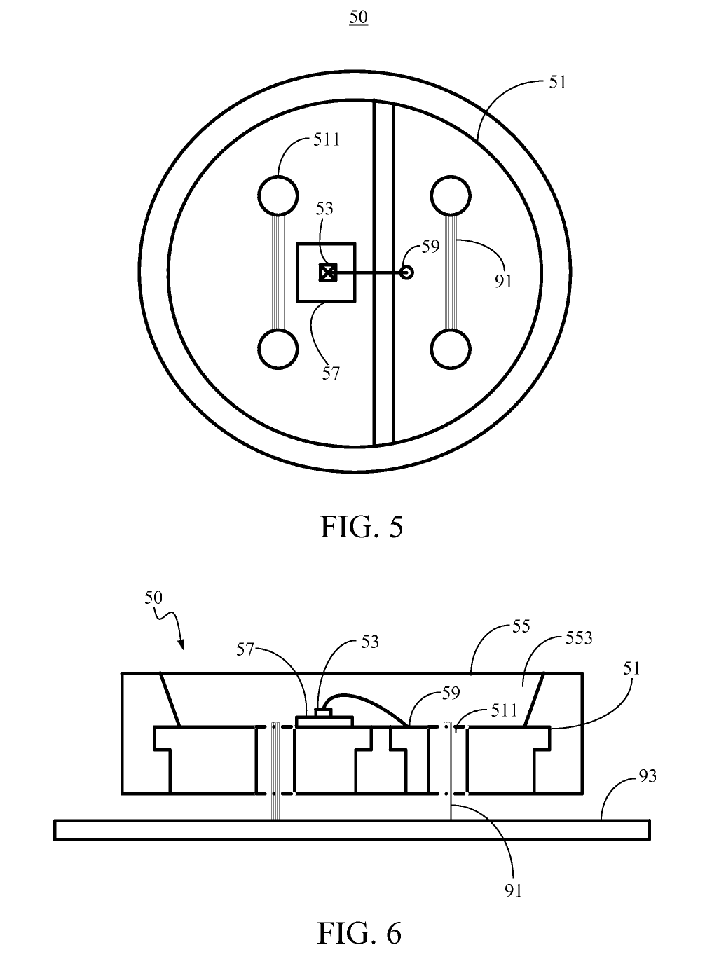

Yet a further embodiment of the present invention further provides an electric component button module to further integrate an electric component with a conventional button. FIGS. 5 and 6 illustrate the top view and side view, respectively, of an LED button module 50 of the present invention. As shown in FIGS. 5 and 6, the LED button module 50 of the present invention is actually an LED module shaped as a button, and comprises a substrate 51, a first electrical pin 57, a second electrical pin 59, an LED die 53 and a mask 55. Like the first embodiment of the aforesaid electric button 10, in this embodiment, the substrate 51 has a plurality of through holes 511 formed therein so that the LED button module 50 can be fastened onto the fabric 93 by the conductive thread 91 extending through the through holes 511. In the preferred example, the substrate 51 may be a printed circuit board (PCB), which is electrically connected to the conductive thread 91 to provide the power supply needed by the two electrical pins 57, 59 and the LED die 53.

Still, in reference to FIGS. 5 and 6, in the LED button module 50 of the present invention, the LED die 53 is fixedly disposed onto the substrate 51 directly, and is electrically connected to the first electrical pin 57 and the second electrical pin 59 of the substrate 51. In the preferred example, the through holes 511 are disposed adjacent to the center position of the substrate 51, which is suitable for use in an automatic sewing machine (not shown) so that the substrate 51 can be quickly sewed onto the fabric 93 by the automatic sewing machine using the conductive thread 91 through the through holes 511. This facilitates an automatic mass production process. Furthermore, the conductive thread 91 is electrically connected to the first electrical pin 57 and the second electrical pin 59 through a printed circuit of the substrate 51. In practicality, the LED button module 50 may be applied to a conductive fabric developed by the present applicant; for example, an LED module array may be formed to display an LED array signal (e.g., a marquee signal or an indicating signal) on the fabric.

The LED button module 50 of the present invention has a mask 55. As in the first embodiment of the aforesaid electric button 10, the mask 55 seals the LED die 53 on the surface of the substrate 51. The mask 55 seals most of the areas of the LED die 53 and the substrate 51 except the through holes for both electrical insulation and moisture isolation purposes to prolong the service life of the LED. In practicality, an external power supply (not shown) is connected to the first electrical pin 57 and the second electrical pin 59 of the substrate 51 by the conductive thread 91 through the printed circuit of the substrate 51, and is then electrically connected to the LED die 53 through the first electrical pin 57 and the second electrical pin 59 so that the LED die 53 emits light. Moreover, in practicality, depending on the optical design requirements of the conventional LED module, a cavity 553 may be formed between the mask 55 and the substrate 51 and be filled and coated with an appropriate optical material. Depending on the requirements of practical applications, different shapes, colors and transparency levels of the mask 55 may be developed to enlarge its application scope.

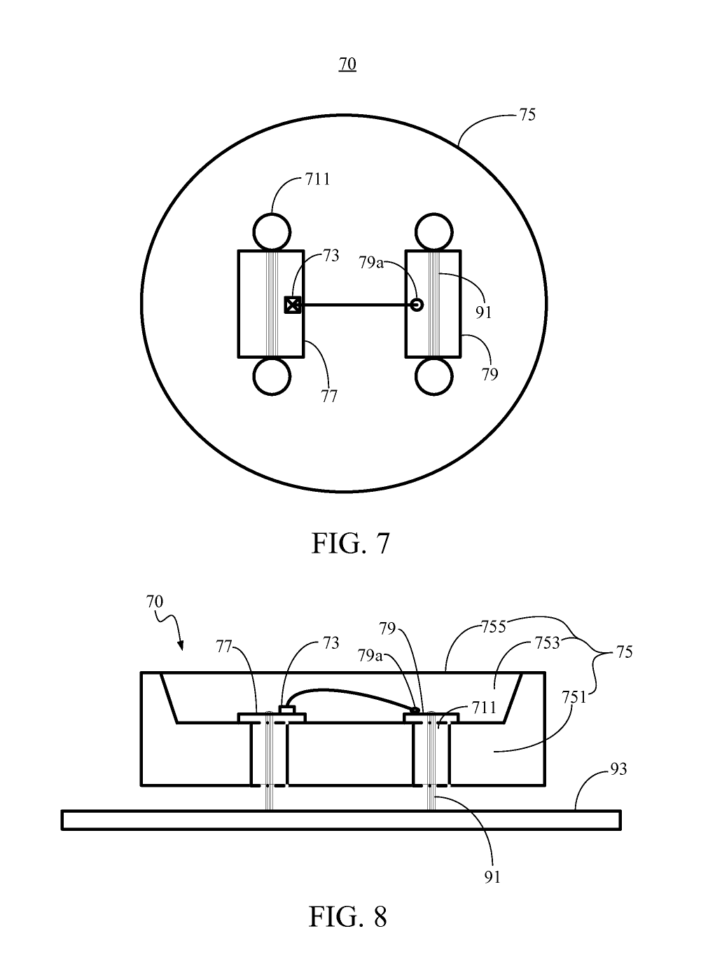

FIGS. 7 and 8 illustrate the top view and side view of an LED button module 70 according to another embodiment of the present invention. As shown in FIGS. 7 and 8, the LED button module 70 of this embodiment comprises a first electrical pin 77, a second electrical pin 79, an LED die 73 and an enclosure 75. Similar to the aforesaid embodiment, the LED die 73 of this embodiment is electrically connected to the first electrical pin 77 via a second electrical pin 79a to the second electrical pin 79. The enclosure 75 of the LED button module 70 comprises at least one through hole 711 formed therein so that the enclosure 75 is sewed onto the fabric 93 by at least one conductive thread 91 through the through hole 711.

Unlike the aforesaid embodiment, the LED button module 70 of this embodiment has the components of the aforesaid LED button module 50 further integrated to make the structure thereof more compact. This can simplify the production process, reduce the number of parts to be produced, reduce the manufacturing cost and facilitate commercialization of products. Specifically, the enclosure 75 of this embodiment is a component that has the substrate 51 and the mask 55 integrally formed. For example, the enclosure 75 of this embodiment may have a base 751 and a housing portion 755 integrally formed through injection molding from a plastic. The base 751 supports the LED die 73, the first electrical pin 77 and the second electrical pin 79, while the housing portion 755 seals the first electrical pin 77, the second electrical pin 79 and the LED die 73 to isolate moisture. It shall be appreciated that depending on the optical design requirements of the conventional LED module, a cavity 753 may be formed between the base 751 and the housing portion 755 and be filled and coated with an appropriate optical material.

In practicality, an external power supply (not shown) is connected to the first electrical pin 77 and the second electrical pin 79 through the conductive thread 91, and is then electrically connected to the LED die 73 through the first electrical pin 77 and the second electrical pin 79 so that the LED die 73 emits light. The LED button module 70 of this embodiment further has dual functions of the conventional LED and the button integrated together to further save materials, reduce the manufacturing cost, decrease the product weight, and improve the product competitiveness.

According to the above descriptions, through the aforesaid solutions of the present invention, the function of the electric component is successfully integrated into the button. Thus, many potential application fields can be developed to add further convenience to the users.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. An electric button, comprising:
a substrate;
at least one electric component, being fixedly disposed on a surface of the substrate and electrically connected to the substrate; and
a mask, sealing the at least one electric component on the surface of the substrate,
wherein the substrate is sewed on a fabric by at least one conductive thread, and is electrically connected to the at least one conductive thread.

2. The electric button as claimed in claim 1, wherein the substrate comprises at least one through hole formed therein so that the substrate is sewed on the fabric by the at least one conductive thread through the at least one through hole.

3. The electric button as claimed in claim 1, wherein the at least one electric component comprises at least one of a light emitting diode (LED), a resistor, a capacitor, a switch, an inductor, a speaker, an integrated circuit (IC) chip, and a combination thereof.

4. The electric button as claimed in claim 3, wherein the at least one electric component is fixedly disposed on the substrate by one of a surface mount technology (SMT) and a welding process.

5. The electric button as claimed in claim 1, wherein the mask has a planar shape.

6. The electric button as claimed in claim 1, wherein the mask has a spherical shape.

7. The electric button as claimed in claim 1, wherein the mask at least has a transparent or translucent area.

8. The electric button as claimed in claim 1, wherein the mask at least seals the at least one electric component and the substrate.

9. The electric button as claimed in claim 1, wherein the substrate is a printed circuit board (PCB).

10. An electric button, comprising:
a substrate;
at least one electric component;
at least one conductive thread, fixedly disposing the at least one electric component on a surface of the substrate and electrically connecting to the at least one electric component; and
a mask, sealing the at least one electric component on the surface of the substrate,
wherein the substrate is sewed on a fabric by the at least one conductive thread.

11. The electric button as claimed in claim 10, wherein the substrate comprises at least one through hole formed therein so that the substrate is sewed on the fabric by the at least one conductive thread through the at least one through hole.

12. The electric button as claimed in claim 10, wherein the at least one electric component comprises at least one of an LED, a resistor, a capacitor, a switch, an inductor, a speaker, an IC chip, and a combination thereof.

13. The electric button as claimed in claim 12, wherein the at least one electric component is fixedly disposed on the substrate by one of a surface mount technology (SMT) and a welding process.

14. The electric button as claimed in claim 10, wherein the mask has a planar shape.

15. The electric button as claimed in claim 10, wherein the mask has a spherical shape.

16. The electric button as claimed in claim 10, wherein the mask at least has a transparent or translucent area.

17. The electric button as claimed in claim 10, wherein the mask at least seals the at least one electric component and the substrate.

18. An LED button module, comprising:
a substrate;
a first electrical pin, being fixedly disposed on a surface of the substrate and electrically connected to the substrate;
a second electrical pin, being fixedly disposed on the surface of the substrate and electrically connected to the substrate;
an LED die, being fixedly disposed on the surface of the substrate and electrically connected to the first electrical pin and the second electrical pin respectively; and
a mask, sealing the LED die on the surface of the substrate.

19. The LED button module as claimed in claim 18, wherein the substrate is a printed circuit board (PCB).

20. The LED button module as claimed in claim 19, wherein the substrate is sewed on a fabric by at least one conductive thread, and the at least one conductive thread is electrically connected to the substrate.

21. An LED button module, comprising:
a first electrical pin;
a second electrical pin;
an LED die, being electrically connected to the first electrical pin and the second electrical pin respectively; and
an enclosure, sealing the first electrical pin, the second electrical pin and the LED die therein.

22. The LED button module as claimed in claim 21, wherein the enclosure comprises at least one through hole formed therein so that the enclosure is sewed on a fabric by at least one conductive thread through the at least one through hole, and the at least one conductive thread is electrically connected to the first electrical pin and the second electrical pin.

23. The LED button module as claimed in claim 22, wherein the enclosure further comprises a housing portion and a base, the base supports the LED die, the first electrical pin and the second electrical pin, the housing portion seals the first electrical pin, the second electrical pin and the LED die, and the housing portion and the base are integrally formed.
